(19) United States
(12) Patent Application Publication
(10) Pub. No.: US 2024/0423100 A1
(43) Pub. Date: Dec. 19, 2024

(54) ENHANCEMENT OF SUPERCONDUCTIVITY VIA RESONANT ANTI-SHIELDING

(71) Applicants: Michael J. Naughton; Krzsztof Kempa

(72) Inventors: Michael J. Naughton; Krzsztof Kempa

(21) Appl. No.: 17/872,833

(22) Filed: Jul. 25, 2022

(51) Int. Cl. H10N 60/10; H10N 60/85

(52) U.S. Cl. CPC H10N 60/10; H10N 60/85

(57) ABSTRACT

A superconductor structure and superlattice are disclosed. The superconductor structure includes a superconductor and an adjacent material. The material can be in direct contact with the superconductor or with an intermediate layer between. The material has a dielectric response that supports a plasmon or plasmon-polaron mode wherein a real part of the dielectric function has a zero-crossing at or near a dominant peak in frequency of the Eliashberg function of the superconductor, the material having a plasmon wave number that is between about one-half to about two times the Fermi wave number of the superconductor, wherein the material enhances a critical temperature of the superconductor. Methods of making the superconductor structure and superlattice are also disclosed.

This application claims the benefit of U.S. Provisional Patent Application Ser. No. 63/226,997, filed Jul. 29, 2021, which is hereby incorporated by reference in its entirety.

### FIELD

The present application relates to enhancement of superconductivity via resonant anti-shielding. More specifically, the present application relates to a superconductor structure having resonant anti-shielding with plasmon-polarons, superlattice and a method of making the superconductor structure and superlattice.

### BACKGROUND

Electromagnetic metamaterial structures have recently been proposed to enhance the critical temperature T_{c} of Bardeen-Cooper-Schrieffer (BCS) superconductivity by modulating the dielectric response. To be successful, such a scheme would require a resonant anti-shielding effect that can lead to a vanishing nonlocal dielectric function of the system. Conventional metamaterials can provide only a local analog of this effect, and so only modest T_{c} enhancements have been found, to date.

Increasing the critical temperature of superconductivity up to and above room temperature has been a “holy grail” of condensed matter physics. Discovery of the so-called high-T_{c} cuprate superconductors in the 1980s, with T_{c} up to 92 K, rekindled the field, and raised hopes that room temperature superconductivity could be in sight. Cuprate T_{c} was increased to 133 K by 1993 but has since stalled there.

Similar sluggish progress has been made on the theoretical front, with the origins of cuprate superconductivity remaining insufficiently clear still today. Even though carrier bosonization remains a key concept, the pairing mechanism seems more subtle than the BCS electron-phonon-electron interaction. True room temperature superconductivity (T_{c}=287 K) was finally achieved recently in an entirely different class of materials, H₂S+CH₄, but the required conditions are currently impractical, as samples must be kept under ultrahigh pressure (>250 GPa). Nevertheless, this achievement demonstrates experimentally that room temperature superconductivity is possible, in a steady state supported by solid state interatomic interactions.

In another recent development, metallic metamaterials have been proposed to increase T_{c} by controlling the dielectric response. Metallic metamaterial structures often rely on plasmonics and nanotechnology, and provide means to effectively customize a metamedium's dielectric and magnetic response functions to obtain various exotic optical properties, such as negative refraction, superlensing, extraordinary transmission, etc. In one scenario, such media were engineered to have a vanishingly small effective electronic dielectric function (sometimes called epsilon-near-zero), and this was conjectured as being advantageous for superconductivity enhancement. However, experimentally observed T_{c} enhancement has been limited to a few degrees kelvin.

The present application is directed to overcoming these and other deficiencies in the art.

### SUMMARY

One aspect of the present disclosure relates to a superconductor structure. The superconductor structure includes a superconductor and a material adjacent the superconductor. The superconductor adjacent to the material includes the superconductor in direct contact with the material or with an intermediate layer therebetween. The material has a dielectric response that supports a plasmon or plasmon-polaron mode wherein a real part of the dielectric function has a zero-crossing at or near a dominant peak in frequency (or equivalently, wavelength, energy or wave number) of the Eliashberg function of the superconductor, the material having a plasmon wave number that is between about one-half to about two times the Fermi wave number of the superconductor, wherein the material enhances a critical temperature of the superconductor.

Another aspect of the present disclosure relates to a method for providing resonant anti-shielding for a semiconductor to enhance a critical temperature of the superconductor. The superconductor is provided. A material is provided adjacent the superconductor. The material has a dielectric response that supports a plasmon or plasmon-polaron mode wherein a real part of the dielectric function has a zero-crossing at or near a dominant peak in frequency of the Eliashberg function of the superconductor, the material having a plasmon wave number that is between about one-half to about two times the Fermi wave number of the superconductor, wherein the material enhances a critical temperature of the superconductor.

The technology of the present disclosure provides dielectric enhancement of superconductivity by employing a superlattice having alternating thin films of a superconductor and a material. The latter material can host plasmon-polarons, long lived and strongly coupled to the superconductor phonon spectrum, yielding robust, nonlocal resonant anti-shielding. An Eliashberg-Leavens approach is utilized to show that resonant anti-shielding can be induced in such a heterostructure and demonstrate that T_{c} up to 250 K can occur in MgB₂ under proper coupling parameters.

Resonant anti-screening induced in a superconductor film sandwiched between topological crystals which support, at their surfaces, plasmon-polaron collective modes characterized by long lifetimes at very large momentum transfer, facilitates robust nonlocality. These plasmon-polarons (hybrids of plasmon and phonon excitations) can strongly modify the dynamics of the electron-phonon interaction in the superconductor and can be adjusted for maximum effect via the topological proximity effect.

These and other aspects of the present disclosure will become apparent upon a review of the following detailed description and the claims appended thereto.

### BRIEF DESCRIPTION OF THE DRAWINGS

FIG. 1A illustrates a superlattice structure having superconductor (S) with adjacent material (M), FIG. 1B illustrates an embodiment of the superlattice structure illustrated in FIG. 1A having adjacent superconductor (S) and material (M) layers in direct contact, FIG. 1C illustrates an embodiment of the superlattice structure having additional phonon-modifier (P) films between the adjacent superconductor (S) and material (M) layers, FIG. 1D and FIG. 1E illustrate embodiments of S-M paired structures, and FIG. 1F and FIG. 1G illustrate embodiments of S-P-M structures;

FIG. 2A illustrates the collective modes of the 2D Dirac electron gas on the surface of a topological crystal (Be₂Se₃) (interpolated from experimental data of Jia et al.): α—mode (blue line), acoustic phonon mode (red line), BZ—Brillouin zone and FIG. 2B illustrates the calculated dielectric function of the 2D Dirac electron gas using Eq. (10) with a step model of α²F: solid line: real part, dashed line: imaginary part;

FIG. 3 illustrates the calculated maximum critical superconducting temperature T_{c,max} versus coupling parameter κ, for Pb (solid line) and MgB₂ (dashed line) on Be₂Se₃; and

FIG. 4 illustrates the effective dielectric and Eliashberg functions of MgB₂ in close contact with Bi₂Se₃, in each panel, the curves are calculated for κ=0 (red-solid lines), 0.8 (dashed-red lines), 1.2 (blue lines) and 1.5 (green lines), in panel (d), the scale for the blue line is to the right, and for other lines to the left, the yellow shaded region in panel (c) represents the condition |\tilde{ε}ₛᵤₚ(ω)|<1, where RAS is possible.

### DETAILED DESCRIPTION

The present application relates to enhancement of superconductivity via resonant anti-shielding. More specifically, the present application relates to a superconductor structure and superlattice having resonant anti-shielding with topological plasmon-polarons and a method of making the superconductor superlattice structure.

One aspect of the present disclosure relates to a superconductor structure. The superconductor structure includes a superconductor and a material adjacent the superconductor. The material has a dielectric response that supports a plasmon or plasmon-polaron mode wherein a real part of the dielectric function has a zero-crossing at or near a dominant peak in frequency of the Eliashberg function of the superconductor, the material having a plasmon wave number that is between about one-half to about two times the Fermi wave number of the superconductor, wherein the material enhances a critical temperature of the superconductor.

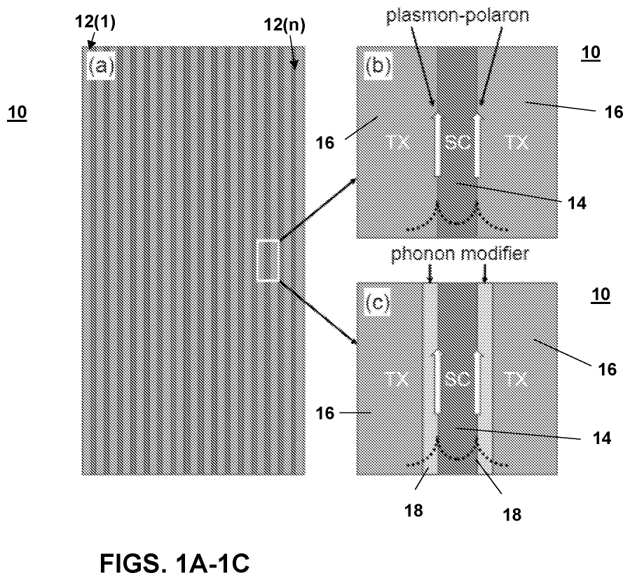

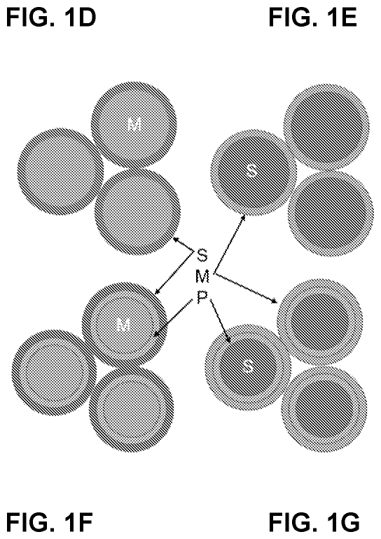

FIG. 1A illustrates a superlattice structure having superconductor (S) with adjacent material (M) designed to exploit the proposed resonant anti-shielding (RAS) effect produced by a surface plasmon-polaron. The superlattice structure shown in FIG. 1A represents a plurality of pairs of quasi-two-dimensional layers. FIG. 1B illustrates an embodiment of the superlattice structure illustrated in FIG. 1A having adjacent superconductor (S) and material (M) layers in direct contact and also indicates the decaying amplitudes of the electric field (dashed lines) produced by the plasmon-polaron mode propagating (arrows) along each interface. FIG. 1C illustrates an embodiment of the superlattice structure having additional phonon-modifier (P) films between the adjacent superconductor (S) and material (M) layers. Note that, due to the topological proximity effect, plasmon-polaron modes occur at the interfaces of the modifiers with the superconductor. FIG. 1D and FIG. 1E illustrate embodiments of S-M paired structures wherein S and M are not necessarily in planar, film form, but are in an arbitrary 3D shape. FIG. 1D and FIG. 1E represent a superlattice of three-dimensional structures of composite concentric pairs, which can be referred to as a series plurality. FIG. 1F and FIG. 1G illustrate embodiments of S-P-M structures wherein S, P and M are not necessarily in planar, film form, but are in an arbitrary 3D shape. FIG. 1F and FIG. 1G represent a superlattice of three-dimensional structures of composite concentric pairs, which can be referred to as a parallel plurality.

FIG. 1A illustrates an exemplary superconductor (SC) superlattice structure 10 of the present technology. In this example, the SC superlattice structure includes a plurality of pairs of layers 12(1)-12(n) each pair is a superconductor structure containing a superconductor layer 14 and a dielectric material layer 16 adjacent one another. The superconductor layer 14 and the adjacent dielectric material layer 16 can include direct physical contact in one example as shown in FIG. 1B or with an intermediate layer between in another example, such as shown in FIG. 1C. Although a plurality of pairs of layers are illustrated and described as a superlattice, it is to be understood that the superconductor structure of the present technology could employ a single pair of layers including a superconductor and a dielectric material. The SC superlattice structure is designed to exploit the proposed resonant anti-shielding (RAS) effect produced by a surface plasmon-polaron. The SC superlattice structure 10 enhances a critical temperature of the superconductor of the superconductor layer 14 by about three to six times the unmodified transition temperature of the superconductor.

Referring now more specifically to FIG. 1B, the superconductor layer 14 has a thickness comparable to or less than the inverse of the Fermi wave number of the superconductor. The superconductor layer 14 also has a thickness less than or equal to the shielding (field penetration) depth of the superconductor. The superconductor layer 14 can include any suitable superconductor amenable to thin film formation. In one example, the superconductor layer 14 includes one of Pb, MgB₂, a cuprate superconductor (examples of which include YBa₂Cu₃O_{7-δ}, Bi₂Sr₂Ca₂Cu₃Oₓ, BiSr₂Ca₂Cu₃Oₓ and others), a pnictide superconductor (examples of which include ReFeAsO (Re=a rare earth element)), or an organic superconductor (examples of which include the (BEDT-TTF)₂X family of materials).

The dielectric material layer 16 in this example is in direct contact with the semiconductor layer 14 as shown in FIG. 1B. In other examples, as discussed in further detail below, a phonon modifier layer 18 is located between the semiconductor layer 14 and the dielectric material layer 16 as shown in FIG. 1C. Referring again to FIG. 1B, as described in further detail below, the dielectric material layer 16 has a dielectric response that supports a plasmon or plasmon-polaron mode. The plasmon-polaron mode is coupled to at least a portion of the phonon spectrum of the superconductor of the superconductor layer 14. A real part of the dielectric function for the dielectric material has a zero-crossing at or near a dominant peak in frequency of the Eliashberg function of the superconductor of the superconductor layer 14. The dielectric material layer 16 also has a plasmon wave number that is between about one-half to about two times the Fermi wave number of the superconductor. In one example, the dielectric material layer 16 includes a topological crystal that has a band structure that includes a bulk bandgap crossed by surface states with linear dispersion. Examples of suitable topological crystals include Bi₂Se₃, Bi₂Te₃, Sb₂Te₃, Bi₁₋ₓSbₓ, TlBiSe₃, although other suitable materials may be employed. In another example, the dielectric material layer 16 includes a surface-structured metamaterial.

The dielectric material layer 16 provides a resonant anti-shielding (RAS) effect produced by a long-lived topological plasmon-polaron mode of the dielectric material layer 16, for example on the surface of a topological crystal (TX), such as Bi₂Se₃, by way of example only. Strong dielectric coupling between plasmon-polarons and the phonon spectrum of the superconductor of the superconductor layer 14 can be anticipated in the SC superlattice structure 10, as illustrated in FIG. 1B.

The basic physics of the anti-shielding effect are illustrated by employing the well-known formula for the dressed combined electron-electron interaction in a jellium metal, as disclosed in Mattuck, “A guide to Feynman diagrams in the many-body problem,” Dover Publications, Inc., New York, 1976, the disclosure of which is incorporated herein by reference in its entirety.

$$\frac{{V}_{q}}{ε} + {\vert \frac{{g}_{q}}{ε} \vert}^{2} \frac{2 {ω}_{q}}{( {ω}^{2} - {ω}_{q}^{2} ) + i δ} = \frac{{V}_{q}}{{ε}_{eff}} , \qquad ( 1 )$$

where ω_{q} is the phonon dispersion, V_{q}=4πe²/q² the bare electrostatic potential, ε the electronic dielectric function of the environment, g_{q} the matrix element for electron-phonon scattering, averaged out/modeled over all electronic states, and iδ a small imaginary constant loss factor. The first term in Eq. (1) is the electron-electron interaction, mediated (screened) by other electrons, and the second, Frohlich, term is the electron-electron interaction mediated by phonons with frequency ω_{q}. This term, when negative, can lead to electron (Cooper) pairing, and to BCS-type superconductivity. This typically occurs at frequency ω≈ω_{q}, with the wavevector q of the order of k_{F} (k_{F}—Fermi wave vector). Eq. (1) also shows that this Cooper pairing interaction can be strongly enhanced by making |ε|<<1, i.e., vanishingly small. This is the RAS effect, since anti-shielding occurs for |ε|<1, thus representing enhancement, rather than suppression (shielding), of the interactions. RAS is much stronger for the Frohlich term in Eq. (1). This is expected, because any more realistic treatment would require a spectral averaging which, as a result of ε changing sign about the vanishing point, would lead to cancellations in the first term ˜1/ε, and accumulations for the second, which goes as ˜1/|ε|². For a typical superconductor that may be employed in superconductor layer 14, ε>1 (and of order 1) and thus, anti-shielding is impossible without some additional mechanism. Similarly, conventional metamaterial structures cannot provide a RAS effect since, while a vanishing of ε at ω≈ω_{q} is relatively easy to accomplish, achieving this simultaneously at very large q≈2k_{F} is an exceedingly difficult task. To show this, consider first a superconducting region in contact with a structured, normal metal, with the smallest structured feature size aₘᵢₙ (e.g., grating period, edge sharpness, surface roughness, etc.) much larger than the thickness of the shielding field penetration layer

$$ζ \approx \frac{1}{q} .$$

In this case, the majority of the superconducting electrons within this layer effectively “see” a flat metallic surface. The effective dielectric function of a metal, which properly describes the nonlocal, flat surface response, has been derived, and for ω=ω_{q} and q=2k_{F}, it is greater than 1. Thus, it represents shielding and is incapable of enhancing Cooper pairing in any structural combination with a superconductor.

Consider now a metamaterial scheme in another limit of aₘᵢₙ≈ζ. In this case, in general, the Fourier spectrum of the response (e.g., fields) could contain components with maximum momentum magnitude qₘₐₓ of order 1/aₘᵢₙ. For example, in the simplest case of a metamaterial surface structured in the form of a 1D grating (say, in the x-direction) with period aₘᵢₙ, the reciprocal lattice vector component Gₓ≈qₘₐₓ≈2π/aₘᵢₙ produces an Umklapp response

$${q}_{x} \to {q}_{x} - {G}_{x} = 2 {k}_{F} - \frac{2 π}{{a}_{min}} \approx 0.$$

Thus, the issue with a large momentum required in the x-direction can be resolved, as long as aₘᵢₙ≈π/k_{F}. However, several additional facts must be kept in mind at this point. First, simple 1D texturing is insufficient for significant enhancement of superconductivity, since this can boost the pairing interaction only in a narrow cone of momentum space, along the chosen direction (x, above). 2D structuring of a metamaterial, with the 2D vector version of the

Umklapp condition \vec{q}→\vec{q}-\vec{G}, improves the situation by providing multiple directional alternatives at the circumference of the Brillouin zone (BZ). One route to this could be to employ surface roughness, with a 2D Fourier spectrum peaked at |qₘₐₓ|≈2π/aₘᵢₙ. Second, aₘᵢₙ needs to be very small. While for cuprates, with k_{F}≈2 nm⁻¹, aₘᵢₙ≈π/k_{F}≈1.5 nm, which is experimentally difficult though manageable, while for good metals, with k_{F}≈20 nm⁻¹, aₘᵢₙ≈π/k_{F}≈0.2 nm, i.e. atomically small, and thus very challenging to control with current nanotechnology. Of course, these conclusions are limited to ζ≈aₘᵢₙ, i.e., the thickness of the superconductor layer 14 or film must be of the same order. Thus, while achieving significant superconductivity enhancement with metamaterials is very difficult, it is in principle possible, and will be discussed in further detail below.

In one example, the dielectric material 16 is a topological crystal in order to provide an RAS effect for the superconductor of the superconductor layer 14. Maxwell's equations allow for the existence of longitudinal plasmon modes in various uniform and non-uniform conductors, for which ε(q, ω)=0. However, conventional plasmon modes occur in the sector of phase space far from the required condition ω≈ω_{q}, with q of the order of k_{F}.

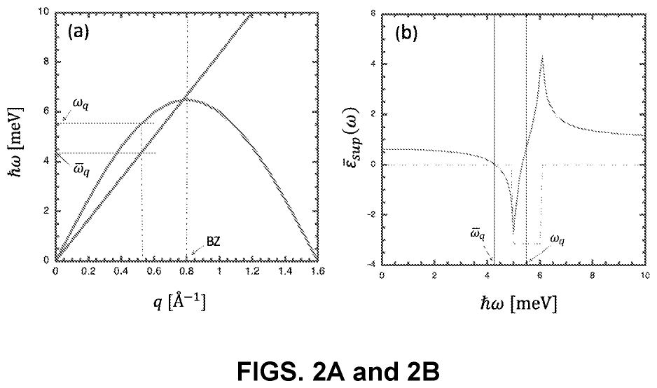

Recently, an unusual plasmonic mode (called an α-mode) was observed in the topological crystal Bi₂Se₃, in that phase space sector, as disclosed in Jia, et al., “Anomalous acoustic plasmon mode from topologically protected states”, Phys. Rev. Lett., 119, 136805 (2017). This mode exists only if Bi₂Se₃ remains topological, i.e., Dirac electrons exist on its surface. The dispersion curve for this mode is close to linear, ω∝q, as illustrated in FIG. 2A, and it is clearly not a pure phonon mode, since it crosses the BZ edge without any momentum Umklapp (LEED showed no surface reconstruction). The most striking observation was that this mode, even at room temperature and very large momentum, remains strong and extremely weakly damped, with the damping rate and intensity almost constant for 2 k_{F}<q<6 k_{F}. All other known plasmon modes are unobservable in that range. An interesting observation was that in the non-topological form of Bi₂Se₃ (induced in situ by Mn doping) this α-mode disappears and is replaced by a conventional, transverse acoustic phonon mode, as shown in FIG. 2A. The new acoustic phonon mode has a standard dispersion, close to that of the α-mode in the first BZ.

A recent theoretical study disclosed in Shvonski, et al., “Plasmon-polaron of the topological metallic surface states”, Phys. Rev. B 99, 125148 (2019), the disclosure of which is incorporated herein by reference in its entirety, is consistent with these discoveries. In particular, it shows that the α-mode is a plasmon-polaron, a hybrid of plasmon excitations of the Dirac surface electrons, and the transverse acoustic phonon mode. This α-mode thus has topological character, as it involves collective electron spin fluctuations of the topological 2D Dirac band electron states at the surface. The α-mode has near perfect suppression of forward and backward scattering, resulting in the experimentally observed ultralow damping, and the absence of Umklapp scattering at the first BZ boundary.

The α-mode is similar to the phonon-polariton mode, the well-known hybrid of photon and phonon excitations. The standard way to obtain the dispersion relation for the polariton is to start with the dispersion relation for photons (light line) ω=qc/\sqrt{ε}, and to replace ε with the usual Lyddane-Sachs-Teller-like phonon formula,

$$ε = {ε}_{eff} = \frac{{ω}_{LO}^{2} - {ω}^{2}}{{ω}_{TO}^{2} - {ω}^{2}} ( TO , LO = transverse ,$$

longitudinal optical). By analogy, one can derive the dispersion relation for the plasmon-polaron by starting with the dispersion relation for the topological 2D Dirac plasmon:

$${ε}_{TI} ( q , ω ) = 1 - \overline{{V}_{q}} Π ( q , ω ) = 0 \qquad ( 2 )$$

where Π(q, ω) is the random phase approximation susceptibility of the electrons [15], and V̅_{q}=V_{q}/2ε. As in the case of a polariton, it is assumed that ε=ε_{eff}, except now ε_{eff} is given by Eq. (1), with ε=ε̅ (a background dielectric constant). This transforms Eq. (2) into the dispersion relation for a plasmon-polaron:

$${ε}_{TI} ( q , ω ) = 1 - \frac{Π ( q , ω )}{2} [ \frac{{V}_{q}}{\overline{ε}} + {\vert \frac{{g}_{q}}{\overline{ε}} \vert}^{2} \frac{2 {ω}_{q}}{( {ω}^{2} - {ω}_{q}^{2} ) + i δ} ] = 0 \qquad ( 3 )$$

Eq. (3) demonstrates that the plasmonic response in this case becomes strongly synchronized/correlated with the phonon oscillations in the vicinity of the interface, on which the topological Dirac electron states reside. In the limit of interest (q of order k_{F} and ω of order ω_{q}), Eq. (3) can be simplified to

$${ε}_{TI} ( q , ω ) \approx 1 + \overline{A} {\vert {g}_{q} \vert}^{2} \frac{2 {ω}_{q}}{( {ω}^{2} - {ω}_{q}^{2} ) + i δ} \approx \frac{( {ω}^{2} - {\overline{ω}}_{q}^{2} )}{( {ω}^{2} - {ω}_{q}^{2} ) + i {δ}^{2}} \qquad ( 4 )$$

with Ā an adjustable parameter, and with the plasmon-polaron frequency given by

$${\overline{ω}}_{q} \approx {ω}_{q} - \overline{A} {\vert {g}_{q} \vert}^{2} < {ω}_{q} . \qquad ( 5 )$$

The plasmon-polaron mode is negatively depolarization shifted, i.e., it follows roughly the phonon mode in the first BZ, but always at frequencies lower than the phonon mode, as shown in FIG. 2A. The scaled dispersion difference

$$Δ = \frac{{ω}_{q} - {\overline{ω}}_{q}}{{ω}_{q}} = \overline{A} {\vert {g}_{q} \vert}^{2} / {ω}_{q}$$

is about 20%, as shown in FIG. 2A, and this experimental result can be used to estimate Ā, a key parameter in determining T_{c}.

In one example, the SC superlattice structure 10 includes the semiconductor layer 14, which is a thin superconductor film that is sandwiched between two thick dielectric material layers 16, which are topological crystals (TX), such as Bi₂Se₃ slabs, as shown in FIG. 1B. It is assumed that the superconductor layer 14 or film is sufficiently thin (thickness<ζ≤1/q), so that RAS is uniformly extended throughout the superconductor of the superconductor layer 14. The topological proximity effect, discussed below, can significantly relax this requirement, as disclosed in Trang, et al., “Conversion of a conventional superconductor into a topological superconductor by topological proximity effect”, Nat. Comm. 11, 159 (2020), the disclosure of which is incorporated herein by reference in its entirety. Then, the effective dielectric function experienced by electrons in the superconductor of the superconductor layer 14 is given by:

$${\overline{ε}}_{sup} ( q , ω ) \approx {ε}_{sup} + [ {ε}_{TI} ( q , ω ) - 1 ] , \qquad ( 6 )$$

where εₛᵤₚ is the dielectric constant of the bulk superconductor, of order 1 in the required domain of phase space, and the term in the square parentheses is the polarizability of the Dirac surface electrons of the topological Bi₂Se₃. It is assumed that phonons of the superconductor of the superconductor layer 14 control the behavior of the plasmon-polaron and generalize the formula in Eq. (3) by relaxing the jellium assumption and by including all relevant phonon bands. Then, with ϵₖ the electron energy, g_{kk′v} the generalized matrix element for scattering between electronic states k′and k through a phonon q=(k′−k, ω_{gv}) in the phonon branch v, and with δ→0⁺, Eq. (6) with the modified Eq. (3) becomes:

$${\overline{ε}}_{sup} ( ω ) = {ε}_{sup} + \overline{A} \frac{1}{N} {\sum }_{{kk}^{′} v} {\vert {g}_{{kk}^{′} v} \vert}^{2} \frac{2 {ω}_{qv}}{( {ω}^{2} - {ω}_{qv}^{2} )} - i π \overline{A} \frac{1}{N} {\sum }_{{kk}^{′} v} {\vert {g}_{{kk}^{′} v} \vert}^{2} δ ( ω - {ω}_{qv} ) δ ( {ϵ}_{k} ) δ ( {ϵ}_{{k}^{′}} ) \qquad ( 7 )$$

where N is the overall normalization factor. The last term in Eq. (7) is recognized as −iπĀα²F(ω), where α²F(ω) is the electron-phonon spectral function, also known as the Eliashberg function of the superconductor of the superconductor layer 14. This allows Eq. (7) to be rewritten as follows:

$${\tilde{ε}}_{sup} ( ω ) = \frac{{\overline{ε}}_{sup} ( ω )}{{ε}_{sup}} = 1 - κ [ {\int }_{0}^{∞} \frac{\overline{ω} [ {α}^{2} F ( \overline{ω} ) ]}{{\overline{ω}}^{2} - {ω}^{2}} d \overline{ω} - i π {α}^{2} F ( ω ) ] \qquad ( 8 )$$

where κ=Ā/εₛᵤₚ. Since εₛᵤₚ is already included in the unshielded α²F(ω), this renormalization reduces the number of adjustable parameters. The integral in Eq. (8) is the Kramers-Kronig transform of −πα²F(ω), and the singular character of the integrand can be eliminated by using the familiar procedure:

$${\int }_{{ω}_{min}}^{{ω}_{max}} \frac{f ( \overline{ω} ) d \overline{ω}}{\overline{ω} - ω} = {\int }_{{ω}_{min}}^{{ω}_{max}} \frac{f ( \overline{ω} ) - f ( ω )}{\overline{ω} - ω} d \overline{ω} + f ( ω ) ln \vert \frac{{ω}_{max} - ω}{{ω}_{min} - ω} \vert \qquad ( 9 )$$

where the integrand on the right is no longer singular, as long as

$$\frac{df}{d ω}$$

is nonsingular at any ω in the integration range. Now, Eq. (8) takes the final form:

$${\tilde{ε}}_{sup} ( ω ) = 1 - κ \{ {α}^{2} F ( ω ) ln \vert \frac{{ω}_{max} - ω}{{ω}_{min} - ω} \vert + {\int }_{{ω}_{min}}^{{ω}_{max}} [ \frac{{α}^{2} F ( \overline{ω} ) - {α}^{2} F ( ω )}{\overline{ω} - ω} + \frac{{α}^{2} F ( ω )}{\overline{ω} + ω} ] d \overline{ω} - i π {α}^{2} F ( ω ) \} \qquad ( 10 )$$

This expression of Eq. (10) can be used to estimate the critical temperature of the superconductor of the superconductor layer 14 sandwiched between two dielectric material layers 16 (Bi₂Se₃ in this example), but first a renormalized value for κ must be estimated. To do that, a Bi₂Se₃ interfacing vacuum is considered. In that case, the phonon spectrum of the dielectric material layer 16 (Bi₂Se₃) controls the physics of the plasmon-polaron, as illustrated in FIG. 1B. Since this is only an order of magnitude estimate of κ, the Eliashberg function of Bi₂Se₃ is modeled as a step function defined as α²F(ω)=1 (typical average value), in the range ωₘᵢₙ<ω<ωₘₐₓ, and α²F(ω)=0 otherwise. Then, using Eq. (10) and choosing κ=1, the result shown in FIG. 2B is obtained, with ω_{q}=5.5 meV, and ω_{q}=4.3 meV. This is in quantitative agreement with the experimental result shown in FIG. 2A at q=0.53 Å⁻¹, and overall (on average) agreement with experiment in the entire q range in the first BZ, where

$$Δ = \frac{{ω}_{q} - {\overline{ω}}_{q}}{{ω}_{q}} \approx 20 \% ( see FIG . 2 B ) .$$

κ is used as a variable, but this estimate limits its variation range to order 1.

Proper scaling of the linearized Eliashberg equations for an Einstein phonon spectrum, as disclosed in Leavens, “A least upper bound on the superconducting transition temperature”, Solid State Commun. 17, 1499-1504 (1975), the disclosure of which is incorporated by reference herein in its entirety, gives the following simple formula for the upper limit of the critical temperature of a superconductor:

$${T}_{c , max} = c ( {μ}^{*} ) {\int }_{0}^{∞} {α}^{2} F ( ω ) d ω \qquad ( 11 )$$

The term c(x) is a very slowly, monotonically decreasing function of x and the Coulomb pseudopotential is:

$${μ}^{*} \approx \frac{N ( μ ) U}{1 + N ( μ ) U ln ( \frac{{ϵ}_{F}}{ℏ {\overline{ω}}_{q}} )} , \qquad ( 12 )$$

where ϵ_{F} is the Fermi energy, and U is the double Fermi surface average of the screened Coulomb potential.

In order to apply Eqs. (11-12) in the presence of the RAS effect, one must renormalize both α²F(ω) and μ*. It is clear from Eq. (7) that α²F(ω) is screened as is the generalized matrix element |g_{kk′v}|², i.e.:

$$\overline{{α}^{2} F ( ω )} = \frac{{α}^{2} F ( ω )}{{\vert {\tilde{ε}}_{sup} ( ω ) \vert}^{2}} . \qquad ( 13 )$$

Clearly, RAS occurs for |ε̅ₛᵤₚ(ω)|<1 and, for |ε̅ₛᵤₚ(ω)|<<1, it strongly enhances the screened Eliashberg function. Regarding the renormalization of μ*, typically

$$ln ( \frac{{ϵ}_{F}}{ℏ {\overline{ω}}_{q}} )$$

ranges from 5 to 10, and N(μ)U>>μ*. Thus, one can approximate Eq. (13) with

$$\overline{{μ}^{*}} \approx {μ}^{*} \approx \frac{1}{ln ( \frac{{ϵ}_{F}}{ℏ {\overline{ω}}_{q}} )} ,$$

i.e. independent of \tilde{ε}ₛᵤₚ(ω). The slow effect of the repulsive Coulomb interaction on shielding is reflecting the cancellations upon spectral averaging of the electron-electron interaction, as mentioned above. Now, the final formula for the maximum critical temperature in the presence of the RAS effect is still given by Eq. (11), but with the Eliashberg function replaced with its renormalized version given by Eq. (13).

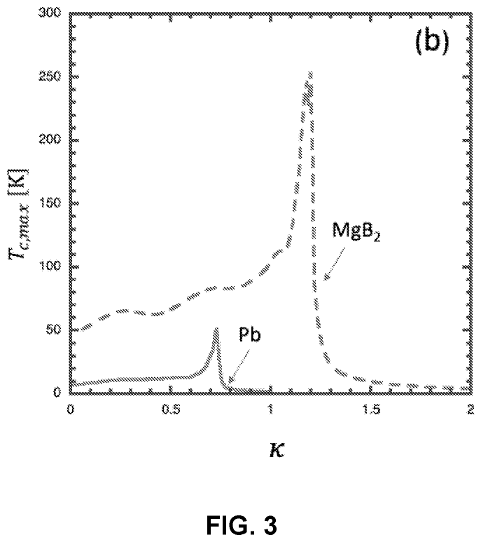

In two examples, the interface of the dielectric material layer 16 (Bi₂Se₃) with the superconductor layer 14 (Pb, a classic low T_{c} superconductor, and with MgB₂, the acknowledged highest T_{c} BCS superconductor) is considered. In these cases, the ab initio calculated Eliashberg function α²F(ω), with λ*=0.1 (0.16) for Pb and for MgB₂ as the superconductor layer 14. Then, following the procedure described above, the results summarized in FIG. 3 are obtained.

FIG. 3 illustrates T_{c,max} versus κ for the superconductor layer 14 as Pb and for MgB₂. Each curve represents the corresponding maximum critical temperature due to the RAS effect, i.e. for κ>0. For no RAS effect, at κ=0, T_{c,max}≈7 K (Pb), and T_{c,max}=47 K (MgB₂). These are close to the experimentally observed values of 7.2 K and 40 K, respectively.

The overall shape of these curves seems universal, with T_{c,max} values first steadily increasing, and then rapidly peaking at strongly enhanced levels, which for Pb is about 50 K, and for MgB₂ exceeds 250 K (approaching room temperature). At even higher values of κ, T_{c,max} collapses to very small values.

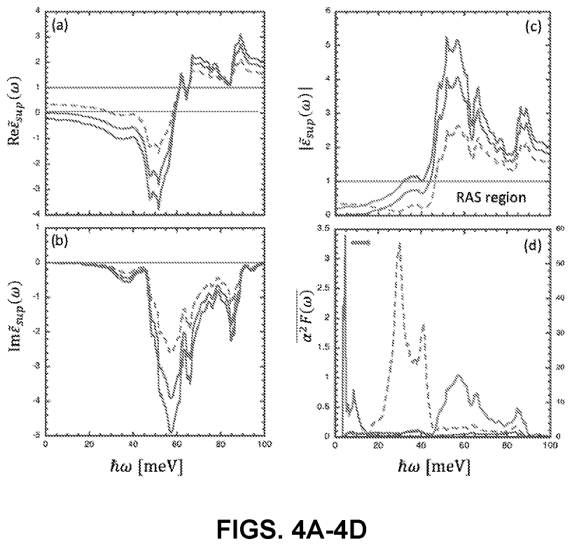

FIG. 4 explains this behavior as it shows the dielectric response and the screened Eliashberg function for MgB₂ for four values of κ: 0 (red-solid lines), 0.8 (dashed-red lines), 1.2 (blue lines) and 1.5 (green lines). The overall shape of \tilde{ε}ₛᵤₚ(ω) in FIG. 4C is similar to that in FIG. 3 for the step model, as expected. The plasmon-polaron mode (occurring at Re \tilde{ε}ₛᵤₚ=0 crossings for small ω, outside the highly damped region) shifts downwards with increasing κ, and disappears for κ>1.2 (Re \tilde{ε}ₛᵤₚ<0).

Comparing FIG. 4C to FIG. 4D clearly illustrates the importance of the RAS effect. It occurs only in the region marked yellow in FIG. 4C, where |\tilde{ε}ₛᵤₚ(ω)|<1. At the peak condition (κ=1.2), |\tilde{ε}ₛᵤₚ(ω)| vanishes for [symbol] ω<20 meV, which overlaps with the remote tails of α²F(ω) for the unscreened (κ=0) case, and leads to the very large renormalized value of α̅²̅F̅(̅ω̅)̅ (approaching 60, as shown in FIG. 4D), in spite of the large screening for [symbol] ω>45 meV (as seen in FIG. 4C). Less spectacular are the α̅²̅F̅(̅ω̅)̅ enhancements in FIG. 4D due to RAS minima for κ=0.8 at [symbol] ω≈30 meV and 42 meV in FIG. 4C. On the other hand, for κ=1.5, there is only very weak RAS for [symbol] ω<30 meV, that cannot compensate the strong shielding for larger frequencies, leading to very small T_{c}.

The enhancement of T_{c,max} for MgB₂ is significant at the peak, but even in the steady region, the enhancement is very strong, well exceeding 100 K. If the same enhancement could be possible for the cuprates (with T_{c}≈90 K), it would yield T_{c,max}≈450 K, well above room temperature at the peak, or a record high 200 K in the steady region. The Eliashberg function for cuprates has two peaks, at 25 and 50 meV, as disclosed in Varelogiannis, “Eliashberg function of cuprates and fullerides from gap measurements”, Phys. Rev. B 50, 15974-15977 (1994), the disclosure of which is incorporated herein by reference in its entirety. In this context, one could look for alternative TXs for the dielectric material layer 16, taking advantage, for example, of the very strong electron-phonon coupling recently observed in a Weyl semimetal, at various phonon branches, as disclosed in Osterhoudt, et al., “Evidence for dominant phonon-electron scattering in Weyl semimetal WP₂”, Phys. Rev. X 11, 011017 (2021), the disclosure of which is incorporated by reference herein in its entirety.

Referring now to FIG. 1C, in one example, the SC superlattice structure 10 further includes a phonon modifier layer 18 located between the superconductor and the material, wherein the phonon density of states of the phonon modifier has a maximum at a frequency higher than a dominant peak in the Eliashberg function of the superconductor. The phonon modifier 18 is configured to improve spectral matching between the plasmon or plasmon-polaron mode in the material layer 18 and the dominant peak in the frequency of the Eliashberg function of the superconductor of the superconductor layer 14. In one example, the phonon modifier 18 is an electrically insulating material.

As discussed above, the key advantage of the topological plasmon-polaron is that it remains weakly damped at large momenta and temperature. This is a unique feature, unmatched by any conventional plasmonic mode. In addition, these modes benefit greatly from the recently discovered topological proximity effect, as disclosed in Trang, et al., “Conversion of a conventional superconductor into a topological superconductor by topological proximity effect”, Nat. Comm. 11, 159 (2020), the disclosure of which is incorporated by reference herein in its entirety, observed at the surface of the topological crystal TlBiSe₃, coated with superconducting Pb. It was shown there that the topological state of the crystal extends through up to 20 monolayers of the superconductor, without any mixing with this superconductor. This could be utilized to control RAS in the superlattice of FIG. 1A by adding additional thin films of a normal material, such as the phonon modifier 18, but with properly adjusted phonon bands to induce the required plasmon-polaron modes, as shown in FIG. 1C. This topological proximity effect is also expected to improve the plasmon-polaron penetration into the superconductor layers 14 or films of the SC superlattice structure.

Further possible architectures include natural or engineered bulk SC-TX layered materials, wherein the properties of the superconductor of the superconductor layer 14 are modulated by the properties of proximate TX of the dielectric material layer 16. For example, the cuprate superconductors generally consist of hole-or electron-doped conducting CuO₂ layers sandwiched by nonconducting layers (e.g., yttrium- or bismuth-oxide). Cuprate systems modified to incorporate known TX layers (e.g., metal chalcogenides) could be generated.

Similarly, many molecular organic superconductors are composed of 2D superconducting layers sandwiched by nonconducting layers, the latter of which might be engineered to have TX character. The same in situ strategy could be applied to MgB₂, the known BCS superconductor with very large, relevant phonon frequencies. Such incorporated topological modifications could produce atomic/molecular layers functioning as charge reservoirs as well as providing the T_{c}-enhancing RAS effect. These kinds of systems could facilitate high temperature superconductivity in multiple physical forms, from single crystalline to nanocrystalline/ceramic, so long as the core TX-superconductor-TX character was preserved.

Another aspect of the present disclosure relates to a method for providing resonant anti-shielding for a semiconductor to enhance a critical temperature of the semiconductor. The superconductor is provided. A material is provided in direct contact with the superconductor. The material has a dielectric response that supports a plasmon or plasmon-polaron mode wherein a real part of the dielectric function has a zero-crossing at or near a dominant peak in frequency of the Eliashberg function of the superconductor, the material having a plasmon wave number that is between about one-half to about two times the Fermi wave number of the superconductor, wherein the material enhances a critical temperature of the superconductor.

Although various embodiments have been depicted and described in detail herein, it will be apparent to those skilled in the relevant art that various modifications, additions, substitutions, and the like can be made without departing from the spirit of the disclosure and these are therefore considered to be within the scope of the disclosure as defined in the claims which follow.

What is claimed is:

1. A superconductor structure comprising:
a superconductor; and
a material adjacent to the superconductor, the material having a dielectric response that supports a plasmon or plasmon-polaron mode wherein a real part of the dielectric function has a zero-crossing at or near a dominant peak in frequency of the Eliashberg function of the superconductor, the material having a plasmon wave number that is between about one-half to about two times the Fermi wave number of the superconductor, wherein the material enhances a critical temperature of the superconductor.

2. The superconductor structure of claim 1, wherein the superconductor has a thickness comparable to or less than the inverse of the Fermi wave number of the superconductor.

3. The superconductor structure of claim 1, wherein the superconductor comprises one of Pb, MgB₂, a cuprate superconductor, a pnictide superconductor, or an organic superconductor.

4. The superconductor structure of claim 1, wherein the material comprises a topological crystal.

5. The superconductor structure of claim 4, wherein topological crystal has a band structure that comprises a bulk bandgap crossed by surface states with linear dispersion.

6. The superconductor structure of claim 1, wherein the material comprises a surface-structured metamaterial.

7. The superconductor structure of claim 1, wherein the plasmon-polaron mode is coupled to at least a portion of the phonon spectrum of the superconductor.

8. The superconductor structure of claim 1, wherein the enhanced critical temperature is about three to six times the unmodified transition temperature of the superconductor.

9. The superconductor structure of claim 1, further comprising a plurality of pairs of quasi-two-dimensional layers of the superconductor and the material forming a superlattice.

10. The superconductor structure of claim 1, further comprising a plurality of composite concentric pairs of three-dimensional superconductor and adjacent material forming a superlattice.

11. The superconductor structure of claim 1, wherein the superconductor is in direct contact with the material.

12. The superconductor structure of claim 1 further comprising:
a phonon modifier located between the superconductor and the adjacent material, wherein the phonon density of states of the phonon modifier has a maximum at a frequency higher than a dominant peak in the Eliashberg function of the superconductor, wherein the phonon modifier is configured to improve spectral matching between the plasmon or plasmon-polaron mode in the material and the dominant peak in the frequency of the Eliashberg function of the superconductor.

13. The superconductor structure of claim 12, wherein the phonon modifier is an electrically insulating material.

14. The superconductor structure of claim 12, further comprising a plurality of layers of the superconductor, phonon modifier and material forming a superlattice.

15. The superconductor structure of claim 12, further comprising a plurality of superconductor, phonon modifier, and material composite three-dimensional structures forming a superlattice.

16. A method for providing resonant anti-shielding for a superconductor to enhance a critical temperature of the superconductor, the method comprising:
providing a superconductor; and
providing a material adjacent the superconductor, the material having a dielectric response that supports a plasmon or plasmon-polaron mode wherein a real part of the dielectric function has a zero-crossing at or near a dominant peak in frequency of the Eliashberg function of the superconductor, the material having a plasmon wave number that is between about one-half to about two times the Fermi wave number of the superconductor, wherein the material enhances a critical temperature of the superconductor.

17. The method of claim 16, wherein the superconductor has a thickness comparable to or less than the inverse of the Fermi wave number of the superconductor.

18. The method of claim 16, wherein the superconductor has a thickness less than or equal to the shielding (field penetration) depth of the superconductor.

19. The method of claim 16, wherein the superconductor comprises one of Pb, MgB₂, a cuprate superconductor, a pnictide superconductor, or an organic superconductor.

20. The method of claim 16, wherein the material comprises a topological crystal.

21. The method of claim 20, wherein topological crystal has a band structure that comprises a bulk bandgap crossed by surface states with linear dispersion.

22. The method of claim 16, wherein the material comprises a surface-structured metamaterial.

23. The method of claim 16, wherein the plasmon-polaron mode is coupled to at least a portion of the phonon spectrum of the superconductor layer.

24. The method of claim 16, further comprising providing a plurality of pairs of layers of the superconductor and the material forming a superlattice.

25. The method of claim 16, further comprising providing a plurality of composite concentric pairs of three-dimensional superconductor and adjacent material forming a superlattice.

26. The method of claim 16, wherein the superconductor is in direct contact with the material.

27. The method of claim 16 further comprising:
providing a phonon modifier located between the superconductor and the adjacent material, wherein the phonon density of states of the phonon modifier has a maximum at a frequency higher than a dominant peak in the Eliashberg function of the superconductor, wherein the phonon modifier is configured to improve spectral matching between the plasmon or plasmon-polaron mode in the material and the dominant peak in the frequency of the Eliashberg function of the superconductor.

28. The method of claim 27, wherein the phonon modifier is an electrically insulating material.

29. The method of claim 27, wherein the enhanced critical temperature is about three to six times the unmodified transition temperature of the semiconductor.

30. The method of claim 27, further comprising providing a plurality of layers of the superconductor, phonon modifier and material forming a superlattice.

31. The superconductor structure of claim 27, further comprising a plurality of superconductor, phonon modifier, and material composite three-dimensional structures forming a superlattice.
